(19) United States
(12) Patent Application Publication
(10) Pub. No.: US 2025/0022883 A1
(43) Pub. Date: Jan. 16, 2025

(54) STRETCHABLE DEVICE

(71) Applicant: Japan Display Inc., Tokyo (JP)

(72) Inventors: Yosuke HYODO, Tokyo (JP); Hiroumi KINJO, Tokyo (JP); Masatomo HISHINUMA, Tokyo (JP)

(73) Assignee: Japan Display Inc., Tokyo (JP)

(21) Appl. No.: 18/767,026

(22) Filed: Jul. 9, 2024

(30) Foreign Application Priority Data
Jul. 11, 2023 (JP) 2023-113831

(51) Int. Cl. H01L 27/12

(52) U.S. Cl. CPC H01L 27/1218

(57) ABSTRACT

According to an aspect, a stretchable device includes: a stretchable substrate comprising bodies and hinges that couple the bodies to each other; and a pair of stretchable resins with the stretchable substrate interposed therebetween. The stretchable device includes a detection region in which a load is capable of being detected and a non-detection region when viewed in a stacking direction in which the stretchable substrate and the stretchable resins overlap. One or more of the hinges are detection hinges each provided with a strain gauge. All of the detection hinges overlap the detection region when viewed in the stacking direction. The stretchable resins each includes: a bonded region that overlaps the non-detection region when viewed in the stacking direction and is bonded to the stretchable substrate; and an unbonded region that overlaps the detection region when viewed in the stacking direction and is not bonded to the stretchable substrate.

### CROSS-REFERENCE TO RELATED APPLICATION

This application claims the benefit of priority from Japanese Patent Application No. 2023-113831 filed on Jul. 11, 2023, the entire contents of which are incorporated herein by reference.

### BACKGROUND

### 1. Technical Field

What is disclosed herein relates to a stretchable device.

### 2. Description of the Related Art

Stretchable devices include a stretchable substrate with excellent elasticity and flexibility. The stretchable substrate includes a resin base member and an array layer provided along the resin base member. The stretchable substrate includes bodies arrayed in a matrix (row-column configuration) and hinges that couple the bodies to each other. The hinge described in Japanese Patent Application Laid-open Publication No. 2020-202208 includes a plurality of arcs and has a meandering shape. When a tensile load acts on the stretchable substrate, for example, the arcs of the hinge expand. As a result, the bodies coupled to opposite ends of the hinge move away from each other, and the stretchable substrate stretches. The hinges include first hinges extending in a first direction from the body and second hinges extending in a second direction.

The stretchable device also includes a pair of stretchable resins with the stretchable substrate interposed therebetween. This pair of stretchable resins is bonded to the stretchable substrate. Therefore, when a load is applied to the stretchable device, and the stretchable resins deform, the stretchable substrate deforms with the deformation of the stretchable resins.

To detect the load acting on a stretchable device, it has recently been considered to provide strain gauges to the hinges and detect the amount of strain (amount of deformation) of the hinges. Specifically, it is considered to detect a load in the first direction with the strain gauges provided to the first hinges and detect a load in the second direction with the strain gauges provided to the second hinges.

When a tensile load in the first direction acts on the stretchable device, for example, each portion of the stretchable resins stretches in the first direction. Therefore, the second hinges bonded to the stretchable resins also stretch (deform) in the first direction. Thus, the strain gauges provided to the second hinges detect a load (hereinafter referred to as noise) in a direction (first direction) different from a direction in which the load is originally intended to be detected (second direction). For these reasons, it is desired to develop a stretchable device that reduces noise input to the strain gauges.

For the foregoing reasons, there is a need for a stretchable device that reduces noise input to strain gauges.

### SUMMARY

According to an aspect, a stretchable device includes: a stretchable substrate comprising a plurality of bodies and a plurality of hinges that couple the bodies to each other; and a pair of stretchable resins with the stretchable substrate interposed therebetween. The stretchable device includes a detection region in which a load is capable of being detected and a non-detection region when viewed in a stacking direction in which the stretchable substrate and the stretchable resins overlap. One or more of the hinges are detection hinges each provided with a strain gauge. All of the detection hinges overlap the detection region when viewed in the stacking direction. The stretchable resins each includes: a bonded region that overlaps the non-detection region when viewed in the stacking direction and is bonded to the stretchable substrate; and an unbonded region that overlaps the detection region when viewed in the stacking direction and is not bonded to the stretchable substrate.

### BRIEF DESCRIPTION OF THE DRAWINGS

FIG. 1 is a plan view of a stretchable device according to a first embodiment;

FIG. 2 is a schematic of a section of the stretchable device according to the first embodiment, and more specifically a sectional view along line II-II of FIGS. 1 and 4;

FIG. 3 is a schematic of a section of the stretchable device according to the first embodiment, and more specifically a sectional view along line III-III of FIGS. 1 and 4;

FIG. 4 is an enlarged view of part of a stretchable substrate according to the first embodiment;

FIG. 5 is an enlarged view of a second hinge according to the first embodiment;

FIG. 6 is an enlarged view of the second hinge according to the first embodiment on which a tensile load in a second direction acts;

FIG. 7 is a schematic plan view of the components of a load detection circuit disposed at a body according to the first embodiment;

FIG. 8 is a diagram schematically illustrating a Wheatstone bridge circuit according to the first embodiment;

FIG. 9 is a schematic of the stretchable device according to the first embodiment on which a tensile load in the second direction acts;

FIG. 10 is a schematic of the stretchable device according to the first embodiment on which a load in a first direction acts;

FIG. 11 is a sectional view of the stretchable device according to a second embodiment taken along a stacking direction;

FIG. 12 is a sectional view of the stretchable device according to a third embodiment taken along the stacking direction;

FIG. 13 is a sectional view of the stretchable device according to a fourth embodiment taken along the stacking direction;

FIG. 14 is a plan view of the relation between a detection region and the stretchable substrate in the stretchable device according to a first modification;

FIG. 15 is a plan view of the relation between the detection region and the stretchable substrate in the stretchable device according to a second modification;

FIG. 16 is a plan view of the stretchable device according to a third modification; and

FIG. 17 is a sectional view of the stretchable device according to the third modification taken along the stacking direction.

### DETAILED DESCRIPTION

Exemplary aspects (embodiments) to embody the present disclosure are described below in greater detail with reference to the accompanying drawings. The contents described in the embodiments below are not intended to limit the disclosure according to the present disclosure. Components described below include components easily conceivable by those skilled in the art and components substantially identical therewith. Furthermore, the components described below may be appropriately combined. What is disclosed herein is given by way of example only, and appropriate modifications made without departing from the spirit of the present disclosure and easily conceivable by those skilled in the art naturally fall within the scope of the present disclosure. To simplify the explanation, the drawings may possibly illustrate the width, the thickness, the shape, and other elements of each unit more schematically than the actual aspect. These elements, however, are given by way of example only and are not intended to limit interpretation of the present disclosure. In the present specification and the drawings, components similar to those previously described with reference to previous drawings are denoted by the same reference numerals, and detailed explanation thereof may be appropriately omitted.

When the term “on” is used to describe an aspect where a first structure is disposed on or above a second structure in the present specification and the claims, it includes both of the following cases unless otherwise noted: a case where the first structure is disposed on and in contact with the second structure, and a case where the first structure is disposed above the second structure with still another structure interposed therebetween.

### First Embodiment

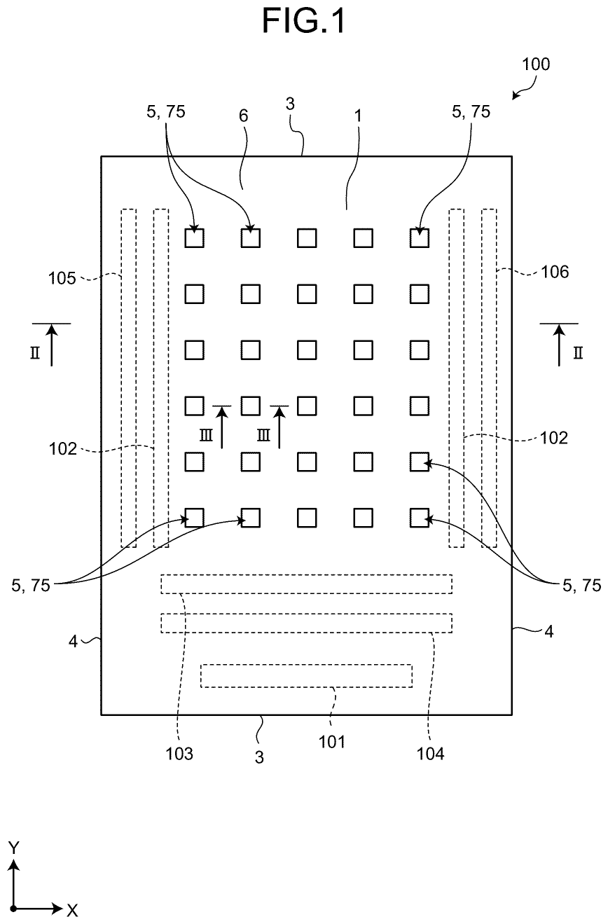

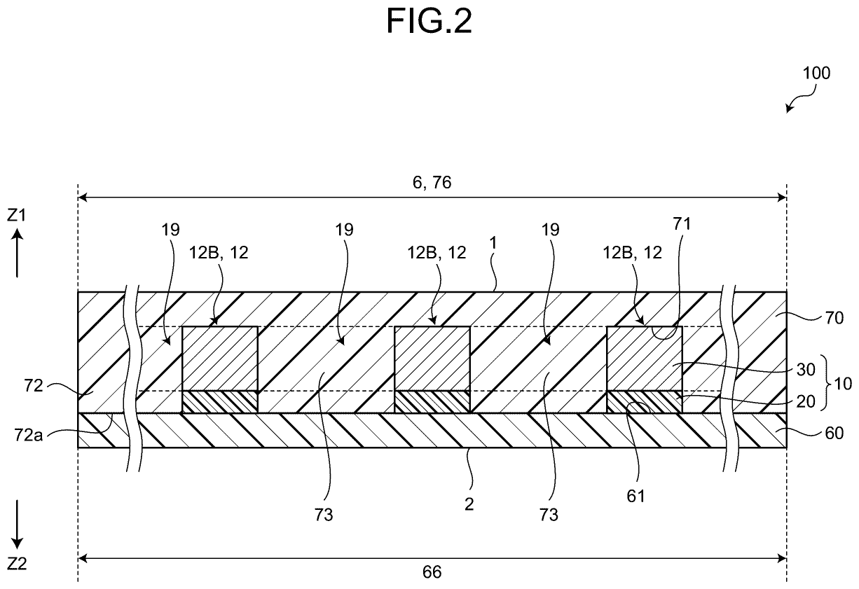

FIG. 1 is a plan view of a stretchable device according to a first embodiment. As illustrated in FIG. 1, a stretchable device 100 has a flat plate shape. The stretchable device 100 has a surface 1 and a back surface 2 (not illustrated in FIG. 1, and refer to FIG. 2) facing opposite to each other. In the following description, the direction parallel to the surface 1 and the back surface 2 is referred to as a planar direction.

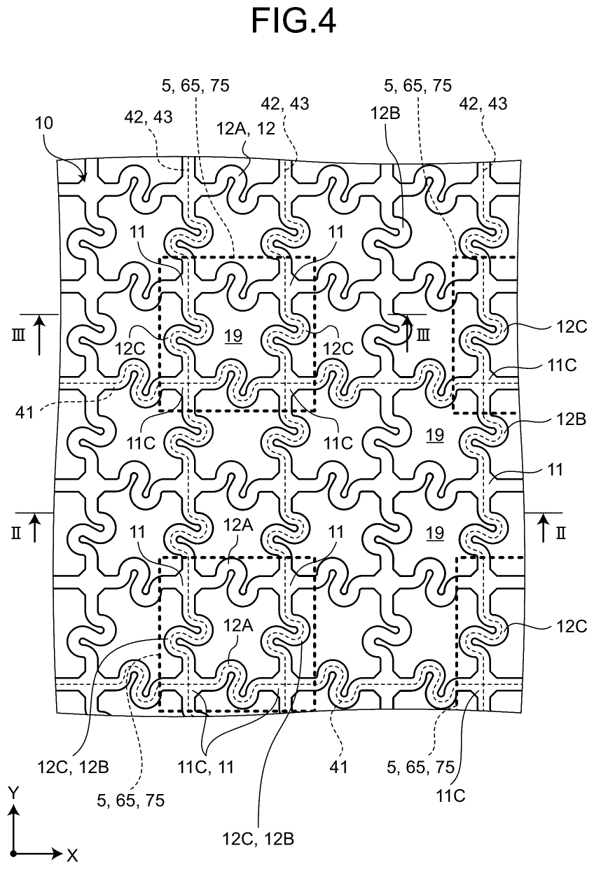

FIG. 2 is a schematic of a section of the stretchable device according to the first embodiment, and more specifically a sectional view along line II-II of FIGS. 1 and 4. As illustrated in FIG. 2, the stretchable device 100 includes a first stretchable resin 60, a stretchable substrate 10, and a second stretchable resin 70 stacked in the order as listed. In other words, the stretchable substrate 10 is interposed between a pair of stretchable resins (the first stretchable resin 60 and the second stretchable resin 70).

The direction in which the first stretchable resin 60, the stretchable substrate 10, and the second stretchable resin 70 are stacked is hereinafter referred to as a stacking direction. In the stacking direction, the direction in which the second stretchable resin 70 is disposed when viewed in the first stretchable resin 60 is referred to as a first stacking direction Z1, and the direction opposite to the first stacking direction Z1 is referred to as a second stacking direction Z2. The view of the stretchable device 100 from the first stacking direction Z1 is referred to as plan view.

As illustrated in FIG. 1, the stretchable device 100 has a rectangular (quadrilateral) shape in plan view. Therefore, the stretchable device 100 has a pair of short sides 3 and a pair of long sides 4. In the following description, a direction parallel to the planar direction and to the short side 3 is referred to as a first direction X, and a direction parallel to the planar direction and to the long side 4 is referred to as a second direction Y.

The stretchable device 100 has a detection region 5 for detecting a load and a non-detection region 6 other than the detection region 5 in plan view. The detection region 5 has a square shape in plan view. In the configuration according to the present embodiment, a plurality of detection regions 5 are provided. The detection regions 5 are equally spaced in the first direction X and the second direction Y. In other words, the detection regions 5 are arrayed in a matrix (row-column configuration).

As illustrated in FIG. 2, the first stretchable resin 60 and the second stretchable resin 70 have insulating, elastic, and flexible properties. The resin used as the first stretchable resin 60 and the second stretchable resin 70 is acrylic elastomer, for example. The first stretchable resin 60 and the second stretchable resin 70 according to the present disclosure are not limited to acrylic elastomer. They may be acrylic resin, epoxy resin, urethane resin, or the like and are not particularly limited.

The first stretchable resin 60 and the second stretchable resin 70 are formed in a plate shape and extend in the planar direction. The surface of the first stretchable resin 60 in the second stacking direction Z2 serves as the back surface (opposite surface) 2 of the stretchable device 100. The first stretchable resin 60 has a counter surface 61 facing the first stacking direction Z1 and opposed to the stretchable substrate 10.

The surface of the second stretchable resin 70 in the first stacking direction Z1 serves as the surface (opposite surface) 1 of the stretchable device 100. The second stretchable resin 70 has a counter surface 71 facing the second stacking direction Z2 and opposed to the stretchable substrate 10. The ends of the second stretchable resin 70 are provided with a frame part 72 that protrudes in the second stacking direction Z2 with respect to the counter surface 71.

The frame part 72 is formed in an annular shape in plan view and surrounds the outer periphery of the stretchable substrate 10. A surface 72a of the frame part 72 in the second stacking direction Z2 adheres to the counter surface 61 of the first stretchable resin 60. Therefore, the first stretchable resin 60 and the second stretchable resin 70 cooperate to serve as a housing that accommodates the stretchable substrate 10.

The stretchable substrate 10 has a plurality of through holes 19 passing therethrough in the stacking direction. The second stretchable resin 70 has a plurality of protrusions 73 protruding from the counter surface 71 in the second stacking direction Z2 and disposed in the through holes 19.

While the through hole 19 according to the present embodiment is filled with the second stretchable resin 70 (protrusion 73), the through hole 19 according to the present disclosure may be filled with the first stretchable resin 60. Alternatively, the through hole 19 may be filled with the first stretchable resin 60 and the second stretchable resin 70. Still alternatively, the through hole 19 may be filled with resin other than the first stretchable resin 60 or the second stretchable resin 70. Still alternatively, the through hole 19 may be a space provided with nothing.

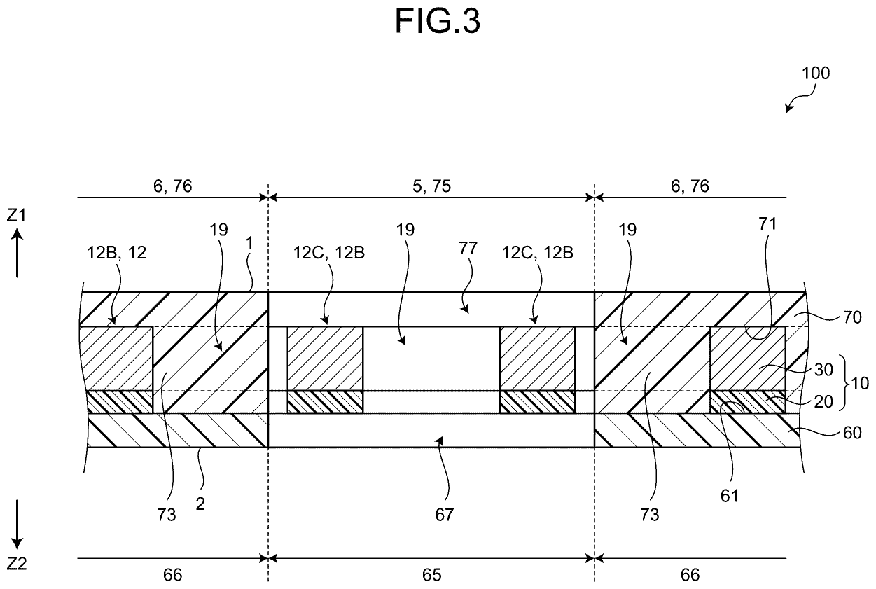

FIG. 3 is a schematic of a section of the stretchable device according to the first embodiment, and more specifically a sectional view along line III-III of FIGS. 1 and 4. As illustrated in FIG. 3, the second stretchable resin 70 has an unbonded region 75 overlapping the detection region 5 in plan view and a bonded region 76 overlapping the non-detection region 6.

The counter surface 71 of the bonded region 76 is provided with an adhesive layer (not illustrated). The bonded region 76 is bonded to the stretchable substrate 10 by the adhesive layer. By contrast, the unbonded region 75 according to the present embodiment is a hole 77 passing through the second stretchable resin 70 in the stacking direction. The hole 77 is formed in a square shape in plan view and has the same shape as that of the detection region 5. Therefore, the second stretchable resin 70 is not bonded to the stretchable substrate 10 in the area overlapping the unbonded region 75.

Similarly, the first stretchable resin 60 has an unbonded region 65 overlapping the detection region 5 in plan view and a bonded region 66 overlapping the non-detection region 6. The counter surface 61 of the bonded region 66 is provided with an adhesive layer (not illustrated). The bonded region 66 is bonded to the stretchable substrate 10 by the adhesive layer. The unbonded region 65 is a hole 67 passing through the first stretchable resin 60 in the stacking direction. The hole 67, which is not specifically illustrated, is formed in a square shape in plan view and has the same shape as that of the detection region 5. Therefore, the first stretchable resin 60 is not bonded to the stretchable substrate 10 in the area overlapping the unbonded region 65.

FIG. 4 is an enlarged view of part of the stretchable substrate according to the first embodiment. As illustrated in FIG. 4, the stretchable substrate 10 includes a plurality of bodies 11 and a plurality of hinges 12 meandering and extending in the planar direction.

The body 11 has a quadrilateral (square) shape in plan view. The body 11 is disposed with its four corners facing the first direction X and the second direction Y. The bodies 11 are arrayed in the first direction X and the second direction Y and are separated from one another. The shape of the body 11 according to the present disclosure in plan view is not limited to a quadrilateral shape and may be circular or other polygonal shapes.

The hinge 12 couples the bodies 11 adjacent to each other. The hinges 12 include two kinds of hinges: a first hinge 12A extending in the first direction X, and a second hinge 12B extending in the second direction Y. The part not provided with the bodies 11 or the hinges 12 in the stretchable substrate 10 serves as the through holes 19 passing through the stretchable substrate 10 in the stacking direction.

As illustrated in FIG. 2, the through holes 19 are filled with the second stretchable resin 70. Therefore, the hinges 12 adjacent to the second stretchable resin 70 in the planar direction have low rigidity, and the stretchable substrate 10 is excellent in elasticity and bendability.

The following describes the hinge 12 in greater detail. When the first hinge 12A is rotated by 90 degrees, it has the same shape as that of the second hinge 12B. Therefore, the second hinge 12B is described below as a representative example.

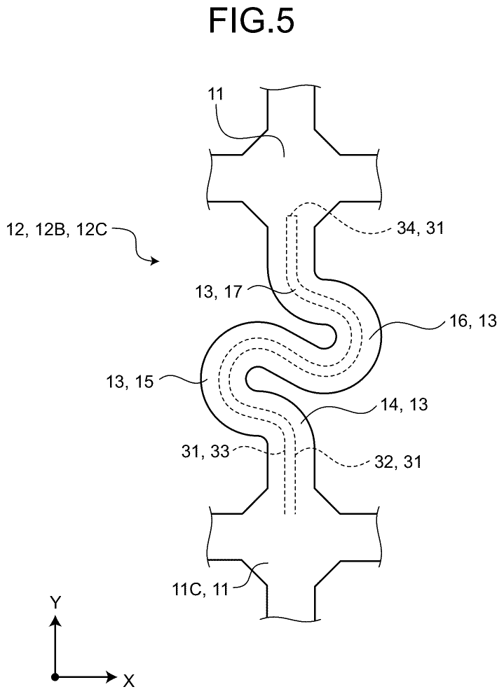

FIG. 5 is an enlarged view of the second hinge according to the first embodiment. As illustrated in FIG. 5, the second hinge 12B has four bends 13 and extends in the second direction Y while meandering. Each bend 13 according to the present embodiment has an arc shape. The bend according to the present disclosure does not necessarily have an arc shape and may have an angular shape. The number of bends is not limited to four.

The four bends 13 are a first arc 14, a second arc 15, a third arc 16, and a fourth arc 17 arranged in the second direction Y in the order as listed. The first arc 14 and the fourth arc 17 each form a quadrant and are bent at 90 degrees. The second arc 15 and the third arc 16 each form a semi-circular arc and are bent at 180 degrees.

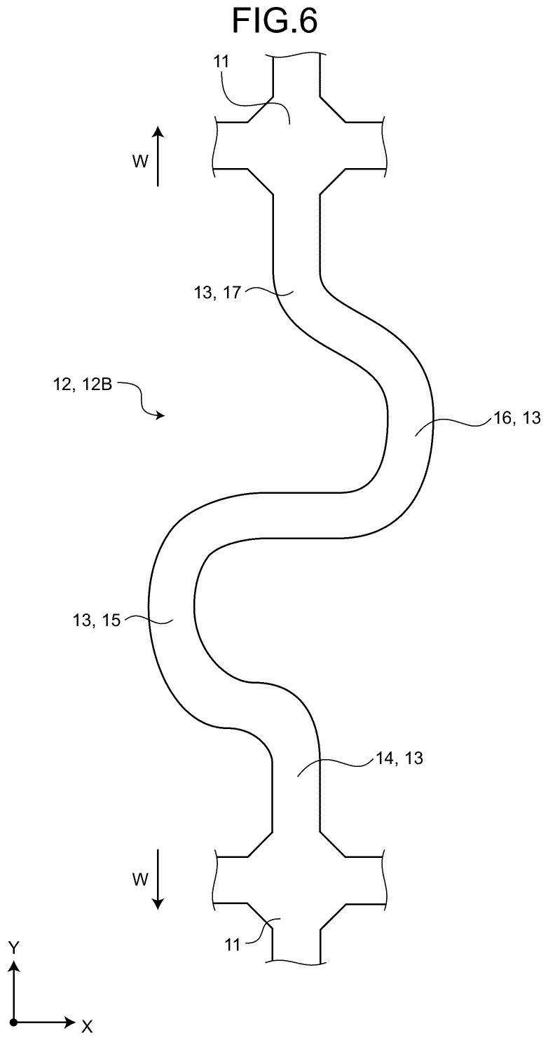

FIG. 6 is an enlarged view of the second hinge according to the first embodiment on which a tensile load in the second direction acts. As illustrated in FIG. 6, when a tensile load in the second direction Y (refer to arrow W in FIG. 6) acts on the second hinge 12B, the first arc 14, the second arc 15, the third arc 16, and the fourth arc 17 are each deformed such that the curvature decreases. As a result, the distance from one end of the second hinge 12B to the other increases, and the bodies 11 move away from each other.

When a compressive load in the second direction Y acts on the second hinge 12B, the first arc 14, the second arc 15, the third arc 16, and the fourth arc 17 are each deformed such that the curvature increases, which is not specifically illustrated. As a result, the distance from one end of the second hinge 12B to the other decreases, and the bodies 11 move closer to each other.

As illustrated in FIG. 4, four hinges 12 (two first hinges 12A and two second hinges 12B) and four bodies 11 are disposed in the area overlapping the detection region 5. The four hinges 12 and the four bodies 11 are exposed in the stacking direction through the hole 67 (unbonded region 65) of the first stretchable resin 60 and the hole 77 (unbonded region 75) of the second stretchable resin 70 (refer to FIG. 3).

As illustrated in FIG. 2, the stretchable substrate 10 includes a resin base member 20 and an array layer 30. The resin base member 20 is a base member for manufacturing the array layer 30 and has elastic, flexible, and insulating properties. The resin base member 20 is made of resin material, such as polyimide.

The array layer 30 is provided on the surface of the resin base member 20 in the first stacking direction Z1. The array layer 30 includes a plurality of insulating layers (not illustrated) stacked in the stacking direction and an electrical circuit (load detection circuit). The electrical circuit (load detection circuit) is insulated from the outside by the insulating layers. Next, the load detection circuit included in the array layer 30 is described in detail.

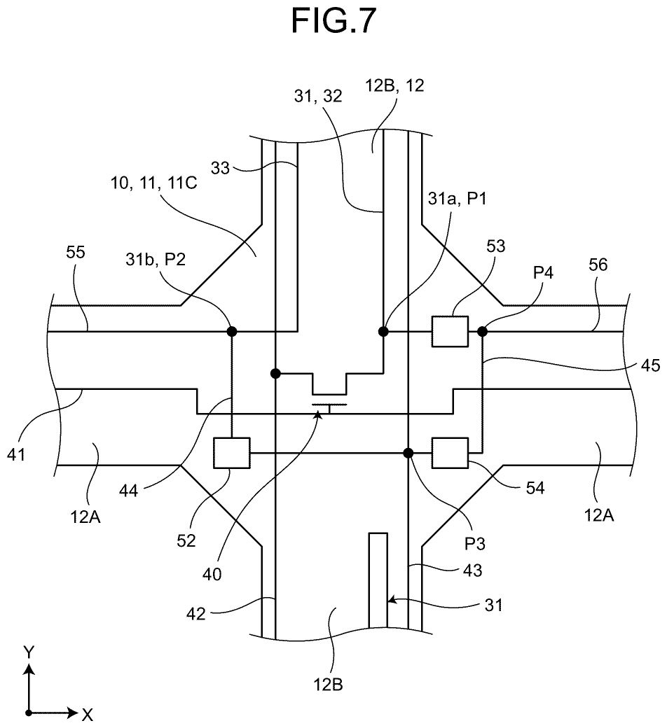

FIG. 7 is a schematic plan view of the components of the load detection circuit disposed on the body according to the first embodiment. The load detection circuit included in the array layer 30 is a circuit that detects a load applied to the stretchable device 100. As illustrated in FIG. 7, the load detection circuit includes a strain gauge 31 (refer to FIG. 5 for more details), a transistor 40, a gate line 41, a first signal line 42, a second signal line 43, first wiring 44, second wiring 45, a second resistor 52, a third resistor 53, a fourth resistor 54, a first potential detection line 55, and a second potential detection line 56.

As illustrated in FIG. 5, the strain gauge 31 is disposed at the hinge 12. The strain gauge 31 includes a first strain gauge 32, a second strain gauge 33, and a coupling portion 34. The first strain gauge 32 and the second strain gauge 33 extend along the hinge 12. The coupling portion 34 couples an end of the first strain gauge 32 and an end of the second strain gauge 33 to each other. The strain gauge 31 according to the present embodiment is twice the length of the conventional strain gauge (strain gauge having the same length as that of the first strain gauge 32). Therefore, the stretchable device 100 according to the present embodiment can detect a larger amount of strain and has higher detection sensitivity. The strain gauge according to the present disclosure may be composed of one strain gauge (only the first strain gauge 32).

Not all the hinges 12 are provided with the strain gauge 31. The strain gauge 31 is provided only to the two second hinges 12B (refer to FIG. 4) overlapping the detection region 5. In the following description, the hinge 12 that overlaps the detection region 5 when viewed in the stacking direction and is provided with the strain gauge 31, is referred to as a detection hinge 12C. All the detection hinges 12C overlap the detection regions 5 when viewed in the stacking direction. As described above, the strain gauge 31 according to the present embodiment is not provided to the two first hinges 12A overlapping the detection region 5. In addition, the strain gauge 31 is not provided to the hinges 12 overlapping the non-detection region 6.

As illustrated in FIG. 7, the transistor 40 is disposed at the body 11. The source electrode of the transistor 40 is coupled to a start end 31a of the strain gauge 31. The coupling point between the transistor 40 and the start end 31a of the strain gauge 31 is hereinafter referred to as a first coupling point P1.

Not all the bodies 11 are provided with the transistor 40. Of the two bodies 11 coupled to opposite ends of the detection hinge 12C, only the body 11 (hereinafter referred to as a detection body 11C) provided with the start end 31a and a terminal end 31b of the strain gauge 31 is provided with the transistor 40. Therefore, in the present embodiment, of the two bodies 11 coupled to the opposite ends of the detection hinge 12C, the body 11 provided with the coupling portion 34 (refer to FIG. 5) is not provided with the transistor 40. In addition, the transistor 40 is not provided to the bodies 11 overlapping the non-detection region 6.

The gate line 41 is disposed over a plurality of first hinges 12A and a plurality of bodies 11 and extends in the first direction X. As illustrated in FIG. 4, the gate line 41 is disposed overlapping the detection bodies 11C. Therefore, some of the first hinges 12A and the bodies 11 are not provided with the gate line 41. The gate line 41 is coupled to the gate electrode of the transistor 40 on the detection body 11C. The gate line 41 is shared by a plurality of transistors 40 arrayed in the first direction X.

The first signal line 42 is disposed over a plurality of second hinges 12B and a plurality of bodies 11 and extends in the second direction Y. Similarly, the second signal line 43 is disposed over a plurality of second hinges 12B and a plurality of bodies 11 and extends in the second direction Y.

In FIG. 4, the first signal line 42 and the second signal line 43 extending in the second direction Y are collectively illustrated as one line. As illustrated in FIG. 4, the first signal line 42 and the second signal line 43 are disposed overlapping the detection bodies 11C. Therefore, some of the second hinges 12B and the bodies 11 are not provided with the first signal line 42 or the second signal line 43.

The first wiring 44 is disposed at the detection body 11C. One end of the first wiring 44 is coupled to the terminal end 31b of the strain gauge 31. The coupling point between the first wiring 44 and the terminal end 31b of the strain gauge 31 is hereinafter referred to as a first intermediate point P2. The other end of the first wiring 44 is coupled to the second signal line 43. The coupling point between the first wiring 44 and the second signal line 43 is hereinafter referred to as a second coupling point P3. The second resistor 52 is provided to the first wiring 44.

The second wiring 45 is disposed at the detection body 11C. The second wiring 45 couples the first coupling point P1 to the second coupling point P3. The third resistor 53 and the fourth resistor 54 are disposed in the second wiring 45. A point positioned between the third resistor 53 and the fourth resistor 54 in the second wiring 45 is hereinafter referred to as a second intermediate point P4.

The first potential detection line 55 is wiring for detecting the potential of the terminal end 31b of the strain gauge 31 and extends from the first intermediate point P2. The first potential detection line 55 is disposed over a plurality of first hinges 12A and a plurality of bodies 11 and extends on one side in the first direction X.

The second potential detection line 56 is wiring for detecting the potential of the second intermediate point P4 of the second wiring 45 and extends from the second intermediate point P4. The second potential detection line 56 is disposed over a plurality of first hinges 12A and a plurality of bodies 11 and extends on the other side in the first direction X.

As described above, the circuit including the strain gauge 31 according to the present embodiment serves as a Wheatstone bridge circuit. The following describes the Wheatstone bridge circuit in detail.

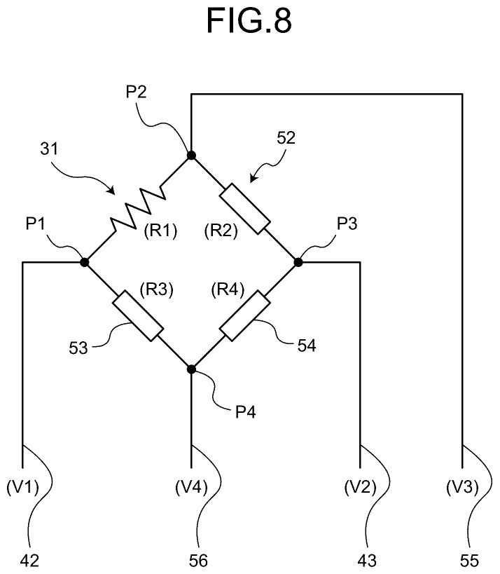

FIG. 8 is a diagram schematically illustrating the Wheatstone bridge circuit according to the first embodiment. A second resistance R2 of the second resistor 52, a third resistance R3 of the third resistor 53, and a fourth resistance R4 of the fourth resistor 54 are equal to a first resistance R1 of the strain gauge 31 when the hinge 12 is not deformed (R1=R2=R3=R4). The second resistor 52, the third resistor 53, and the fourth resistor 54 are provided to the body 11. Therefore, the amount of change in their resistances is zero when the hinge 12 is deformed.

To detect the amount of strain, the first signal line 42 is supplied with a detection signal having a predetermined first potential V1. The second signal line 43 is supplied with a second potential V2 lower than the first potential V1 (V2>V1). The second potential V2 according to the present embodiment is 0 V. Therefore, when the transistor 40 is ON, the potential of the first coupling point P1 (start end 31a of the strain gauge 31) becomes the first potential V1.

When the hinge 12 does not deform, the resistance of the strain gauge 31 remains the first resistance R1. Thus, the first resistance R1 of the strain gauge 31, the second resistance R2 of the second resistor 52, the third resistance R3 of the third resistor 53, and the fourth resistance R4 of the fourth resistor 54 are equal to one another. Therefore, a potential V3 of the first intermediate point P2 read by the first potential detection line 55 is equal to a potential V4 of the second intermediate point P4 read by the second potential detection line 56.

By contrast, when the hinge 12 deforms and the resistance of the strain gauge 31 changes, the first resistance R1 changes. In other words, the potential V3 of the first intermediate point P2 changes. As a result, a potential difference is generated between the first intermediate point P2 and the second intermediate point P4. Therefore, the amount of change in resistance of the strain gauge 31 can be detected by detecting the potential V3 and the potential V4.

As illustrated in FIG. 1, the array layer 30 includes a coupler 101, gate line drive circuits 102, a first signal line selection circuit 103, a second signal line selection circuit 104, a first potential detection line selection circuit 105, and a second potential detection line selection circuit 106 to drive the load detection circuit. The coupler 101, the gate line drive circuit 102, the first signal line selection circuit 103, the second signal line selection circuit 104, the first potential detection line selection circuit 105, and the second potential detection line selection circuit 106 are disposed at the ends of the stretchable device 100 in the non-detection region 6 in plan view.

The coupler 101 is coupled to a drive integrated circuit (IC) disposed outside the stretchable device 100. The drive IC may be mounted as a chip on film (COF) on a flexible printed circuit board or a rigid board, which is not illustrated, and coupled to the coupler 101.

The gate line drive circuit 102 is a circuit that drives a plurality of gate lines 41 (refer to FIG. 7) based on various control signals supplied from the drive IC. The gate line drive circuit 102 sequentially or simultaneously selects the gate lines 41 and supplies gate drive signals to the selected gate line 41.

The first signal line selection circuit 103 is a switch circuit that sequentially or simultaneously selects a plurality of first signal lines 42. The first signal line selection circuit 103 couples the first signal line 42 to the drive IC based on selection signals supplied from the drive IC. As a result, the predetermined first potential V1 is applied to the first signal line 42.

The second signal line selection circuit 104 is a switch circuit that sequentially or simultaneously selects a plurality of second signal lines 43. The second signal line selection circuit 104 couples the second signal line 43 to the drive IC based on selection signals supplied from the drive IC. As a result, the predetermined second potential V2 is applied to the second signal line 43.

The first potential detection line selection circuit 105 is a switch circuit that sequentially or simultaneously selects a plurality of first potential detection lines 55. The first potential detection line selection circuit 105 couples the selected first potential detection line 55 to the drive IC based on selection signals supplied from the drive IC. As a result, the potential V3 of the first intermediate point P2 is transmitted to the drive IC.

The second potential detection line selection circuit 106 is a switch circuit that sequentially or simultaneously selects a plurality of second potential detection lines 56. The second potential detection line selection circuit 106 couples the selected second potential detection line 56 to the drive IC based on selection signals supplied from the drive IC. As a result, the potential V4 of the second intermediate point P4 is transmitted to the drive IC. The following describes a case where a load is applied to the stretchable device 100.

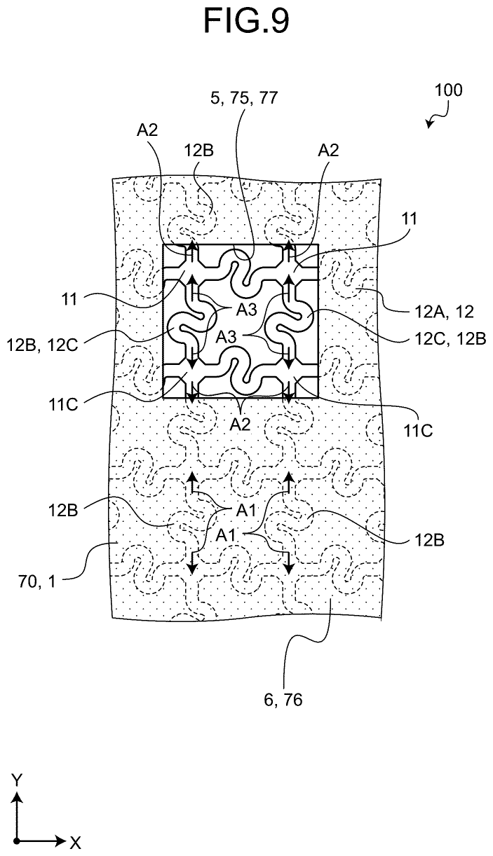

FIG. 9 is a schematic of the stretchable device according to the first embodiment on which a tensile load in the second direction acts. When a tensile load in the second direction Y is applied to the stretchable device 100, each portion of the first stretchable resin 60 and the second stretchable resin 70 stretches in the second direction Y. With this deformation, the second hinges 12B overlapping the non-detection region 6 (and bonded to the bonded regions 66 and 76) stretch in the second direction Y (refer to arrows A1 in FIG. 9).

By contrast, the detection hinges 12C (second hinges 12B) overlapping the detection region 5 are not bonded to the first stretchable resin 60 or the second stretchable resin 70. Therefore, no load is directly transmitted from the first stretchable resin 60 and the second stretchable resin 70 to the detection hinges 12C.

On the other hand, the four bodies 11 overlapping the detection region 5 are coupled to the hinges 12 overlapping the non-detection region 6. Therefore, the four bodies 11 overlapping the detection region 5 are subjected to the tensile load in the second direction Y transmitted from the hinges 12 overlapping the non-detection region 6 (refer to arrows A2 in FIG. 9). As a result, the detection hinges 12C are pulled in the second direction Y (refer to arrows A3 in FIG. 9) and stretch in the second direction Y. Thus, the strain gauges 31 are distorted, thereby detecting the tensile load in the second direction Y.

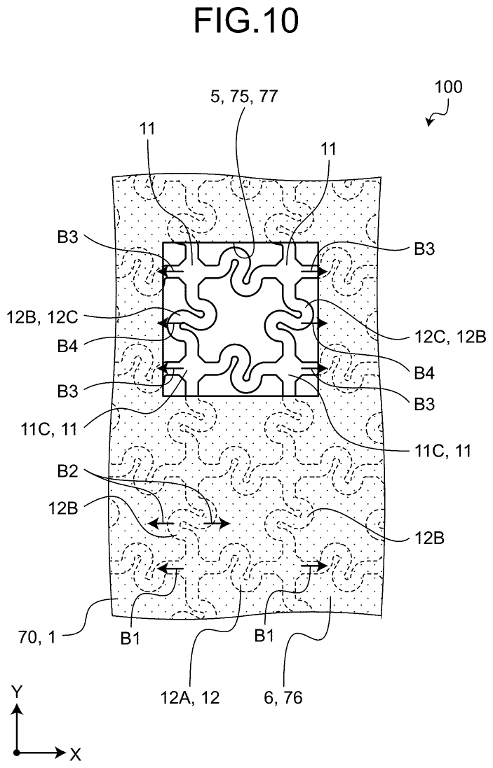

FIG. 10 is a schematic of the stretchable device according to the first embodiment on which a tensile load in the first direction acts. When a tensile load in the first direction X is applied to the stretchable device 100, each portion of the first stretchable resin 60 and the second stretchable resin 70 stretches in the first direction X. With this deformation, the first hinges 12A overlapping the non-detection region 6 (and bonded to the bonded regions 66 and 76) stretch in the first direction X (refer to arrows B1 in FIG. 10). The second hinges 12B overlapping the non-detection region 6 also stretch in the first direction X (refer to arrows B2 in FIG. 10). The load in the first direction X acting on the second hinges 12B is the cause of noise.

On the other hand, the four bodies 11 overlapping the detection region 5 are subjected to the tensile load in the first direction X transmitted from the hinges 12 overlapping the non-detection region 6 (refer to arrows B3 in FIG. 10). As a result, the two bodies 11 (one of them is the detection body 11C) coupled by the detection hinge 12C move in the same direction (first direction X). The detection hinge 12C moves in the same direction as the two bodies 11 coupled thereto (refer to arrow B4 in FIG. 10) and does not deform.

In the stretchable device 100 according to the first embodiment described above, the detection hinge 12C (strain gauge 31) is disposed overlapping the detection region 5. The holes 67 and 77 (unbonded regions 65 and 75) are formed overlapping the detection region 5. With this configuration, no load is directly applied to the detection hinge 12C from the first stretchable resin 60 and the second stretchable resin 70. Therefore, the strain gauge 31 is not subjected to noise, which is load in a direction (first direction X) different from the direction in which the load is originally intended to be detected (second direction Y).

While the stretchable device 100 according to the first embodiment has been described above, the present disclosure is not limited to the example described in the first embodiment. For example, the area overlapping the detection region 5 according to the first embodiment is provided with a plurality of hinges 12, and the strain gauge 31 is provided only to some (second hinges 12B) of the hinges 12, but the present disclosure is not limited thereto. The strain gauge 31 according to the present disclosure may be provided to the first hinges 12A overlapping the detection region 5. Alternatively, the strain gauge 31 may be provided to all the hinges 12 disposed in the area overlapping the detection region 5.

While the strain gauge 31 according to the first embodiment is provided only to the hinges 12 overlapping the detection region 5, the strain gauge 31 may be provided to the hinges 12 in the area overlapping the non-detection region 6. The hinges 12 overlapping the non-detection region 6, however, are subjected to the load transmitted from the stretchable resins. Therefore, it is preferable to correct and use the results of detection by the strain gauge 31.

While the first stretchable resin 60 and the second stretchable resin 70 according to the first embodiment are unbonded to the stretchable substrate 10 by forming the holes 67 and 77 in the unbonded regions 65 and 75, the present disclosure is not limited thereto. The following describes other embodiments that make the detection hinge 12C unbonded by components other than the holes 67 and 77. The following description focuses on the differences from the embodiment described above.

### Second Embodiment

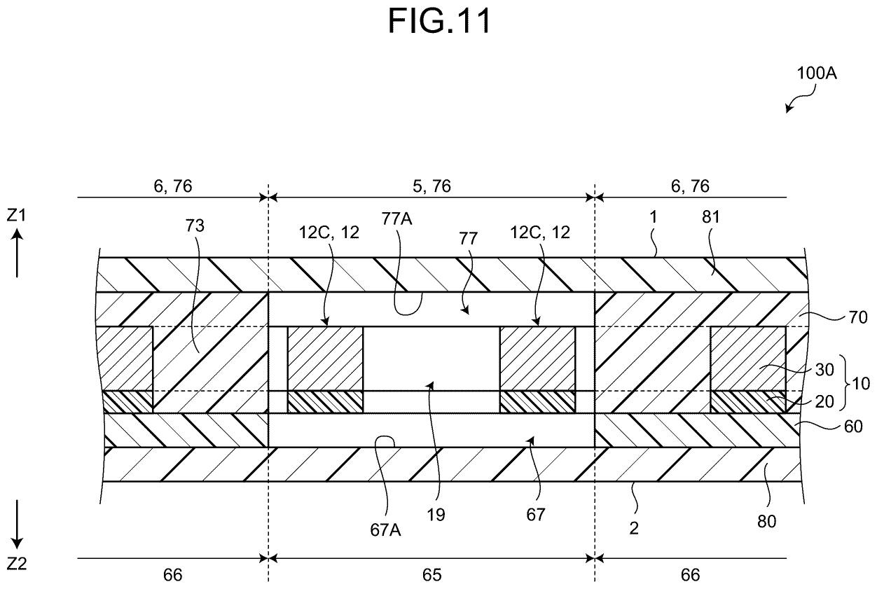

FIG. 11 is a sectional view of the stretchable device according to a second embodiment taken along the stacking direction. As illustrated in FIG. 11, a stretchable device 100A according to the second embodiment is different from the first embodiment in that the stretchable device 100A includes a third stretchable resin 80 disposed on the surface of the first stretchable resin 60 in the second stacking direction Z2. The stretchable device 100A according to the second embodiment is different from the first embodiment in that the stretchable device 100A includes a fourth stretchable resin 81 disposed on the surface of the second stretchable resin 70 in the first stacking direction Z1.

The third stretchable resin 80 and the fourth stretchable resin 81 are formed in a plate shape and extend in the planar direction. The third stretchable resin 80 is bonded to the first stretchable resin 60 by an adhesive, which is not illustrated. Therefore, the hole 67 in the first stretchable resin 60 is covered by the third stretchable resin 80. The surface of the third stretchable resin 80 in the second stacking direction Z2 serves as the back surface 2 (opposite surface). The hole 67 is closed by the third stretchable resin 80 and serves as a recessed surface 67A recessed toward the back surface 2 (opposite surface).

Similarly, the fourth stretchable resin 81 is bonded to the second stretchable resin 70 by an adhesive, which is not illustrated. Therefore, the hole 77 in the second stretchable resin 70 is covered by the fourth stretchable resin 81. The surface of the fourth stretchable resin 81 in the first stacking direction Z1 serves as the surface 1 (opposite surface). The hole 77 is closed by the fourth stretchable resin 81 and serves as a recessed surface 77A recessed toward the surface 1 (opposite surface).

As described above, the recessed surfaces 67A and 77A according to the second embodiment are formed in the unbonded regions 65 and 75. Therefore, the detection hinge 12C of the stretchable substrate 10 faces the recessed surfaces 67A and 77A and is not bonded to the stretchable resins (the first stretchable resin 60, the second stretchable resin 70, the third stretchable resin 80, and the fourth stretchable resin 81). As a result, no load is transmitted from the stretchable resins to the hinge 12, and no noise is input to the strain gauge 31 also in the second embodiment.

While the second embodiment has been described above, the stretchable resins according to the present disclosure may have the following structure: the first stretchable resin 60 and the third stretchable resin 80 are integrally formed, or the second stretchable resin 70 and the fourth stretchable resin 81 are integrally formed.

### Third Embodiment

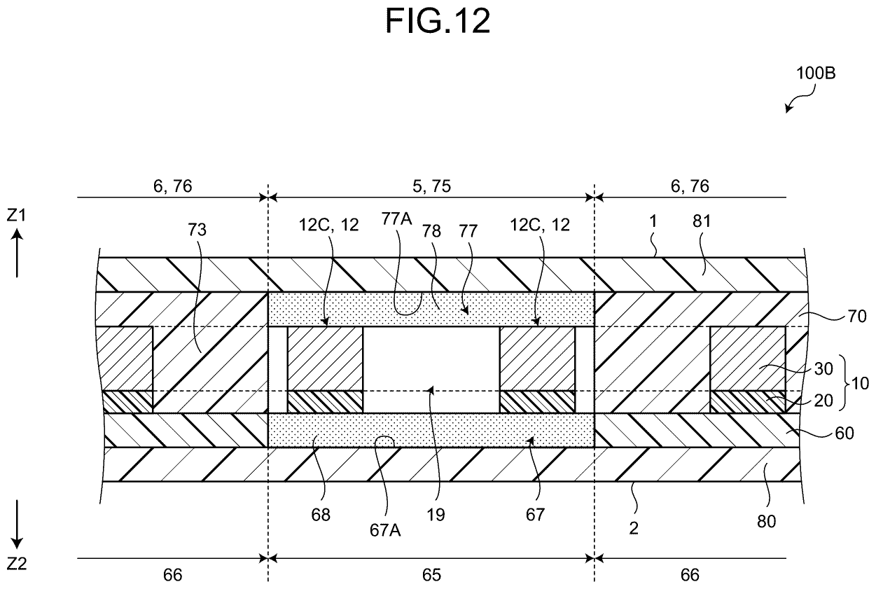

FIG. 12 is a sectional view of the stretchable device according to a third embodiment taken along the stacking direction. A stretchable device 100B according to the third embodiment is different from the second embodiment in that a viscous fluid 68 is provided in the recessed surface 67A. The stretchable device 100B according to the third embodiment is different from the second embodiment in that a viscous fluid 78 is provided in the recessed surface 77A.

Examples of the viscous fluids 68 and 78 include, but are not limited to, gels, sols, silicone oils, etc. The viscous fluids 68 and 78 are in contact with the stretchable substrate 10. Therefore, the viscous fluids 68 and 78 preferably have a small frictional force to reduce the load transmitted to the stretchable substrate 10.

In the configuration according to the third embodiment, the hinges 12 and the bodies 11 of the stretchable substrate 10 overlapping the detection region 5 are in contact with the viscous fluids 68 and 78. Therefore, heat contained in the hinges 12 (including the detection hinges 12C) and the bodies 11 is transmitted to the viscous fluids 68 and 78. This configuration reduces the temperature difference between the strain gauge 31 (refer to FIG. 4) included in the detection hinge 12C and each of the second resistor 52, the third resistor 53, and the fourth resistor 54 (refer to FIG. 7) included in the body 11, thereby achieving temperature compensation of the Wheatstone bridge circuit.

The viscous fluids 68 and 78 according to the present disclosure may include high thermal conductive filler. This configuration can further reduce the temperature difference between the strain gauge 31, the second resistor 52, the third resistor 53, and the fourth resistor 54.

### Fourth Embodiment

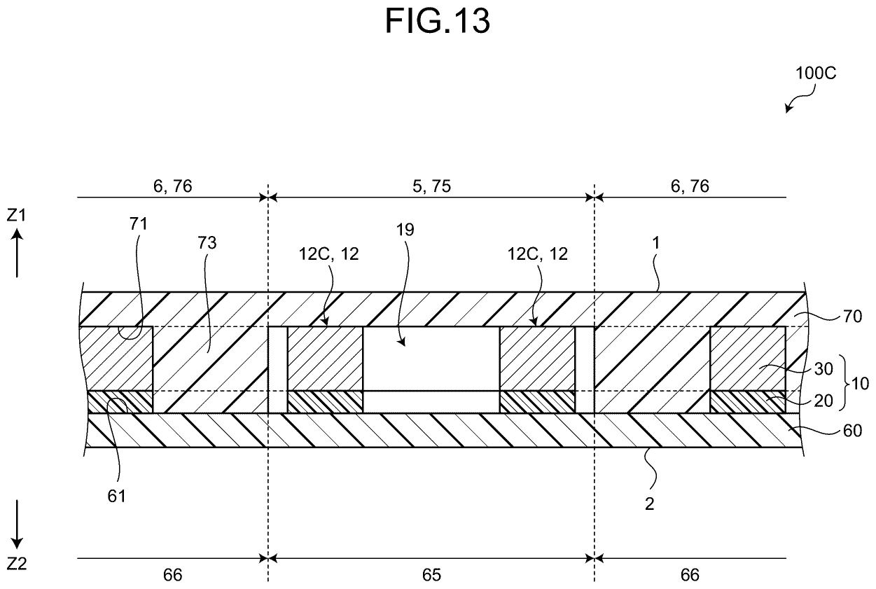

FIG. 13 is a sectional view of the stretchable device according to a fourth embodiment taken along the stacking direction. As illustrated in FIG. 13, a stretchable device 100C according to the fourth embodiment is different from the first embodiment in that the hole 67 is not formed in a first stretchable resin 60. In other words, in the first stretchable resin 60, the counter surface 61 of the unbonded region 65 is in contact with the stretchable substrate 10. The counter surface 61 of the unbonded region 65, however, is not provided with an adhesive. In other words, when a load is applied to the first stretchable resin 60, the counter surface 61 of the unbonded region 65 slides on the stretchable substrate 10.

Similarly, the stretchable device 100C according to the fourth embodiment is different from the first embodiment in that the hole 77 is not formed in a second stretchable resin 70. In other words, in the second stretchable resin 70, the counter surface 71 of the unbonded region 75 is in contact with the stretchable substrate 10. The counter surface 71 of the unbonded region 75, however, is not provided with an adhesive. In other words, when a load is applied to the second stretchable resin 70, the counter surface 71 of the unbonded region 75 slides on the stretchable substrate 10.

With the configuration according to the fourth embodiment, the load from the first stretchable resin 60 and the second stretchable resin 70 is less likely to be transmitted to the detection hinge 12C. Therefore, this configuration can make noise less likely to be input to the strain gauge 31. In the fourth embodiment, it is preferable to perform processing for reducing the frictional force of the counter surfaces 61 and 71 of the unbonded regions 65 and 75.

The above has described the embodiments for reducing the load that is transmitted to the hinge (detection hinge). While the detection region 5 (unbonded regions 65 and 75) according to the first embodiment is formed in a square shape in plan view, for example, the shape of the detection region 5 according to the present disclosure is not particularly limited and may be circular, elliptic, rectangular, or other shapes.

While one detection region 5 (unbonded regions 65 and 75) according to the first embodiment is provided with four hinges 12 and four bodies 11, the present disclosure is not limited thereto. The following describes modifications.

### First Modification

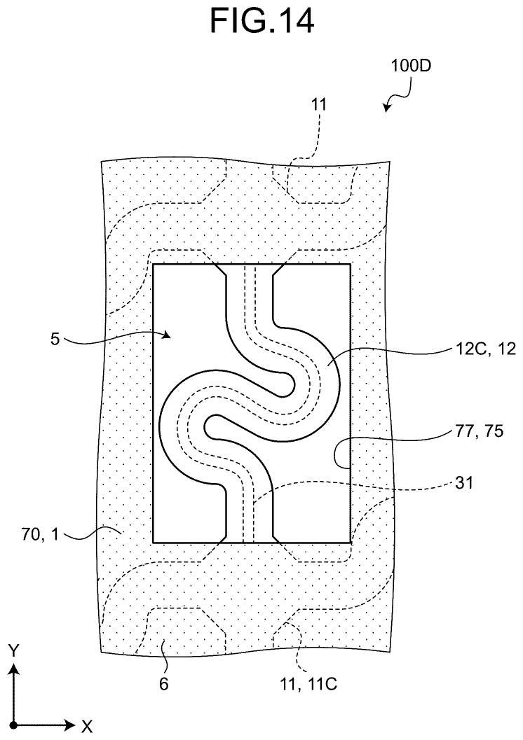

FIG. 14 is a plan view of the relation between the detection region and the stretchable substrate in the stretchable device according to a first modification. As illustrated in FIG. 14, the detection region 5 in a stretchable device 100D according to the first modification overlaps only one hinge 12 (detection hinge 12C). In other words, only the hinge 12 (detection hinge 12C) is exposed through the holes 67 and 77 (unbonded regions 65 and 75) in the first stretchable resin 60 and the second stretchable resin 70. With the configuration according to the first modification, none of the detection hinges 12C are bonded to the first stretchable resin 60 or the second stretchable resin 70. Therefore, the detection hinge 12C does not follow the deformation of the first stretchable resin 60 and the second stretchable resin 70, and the strain gauge 31 does not detect noise (load in the first direction X).

### Second Modification

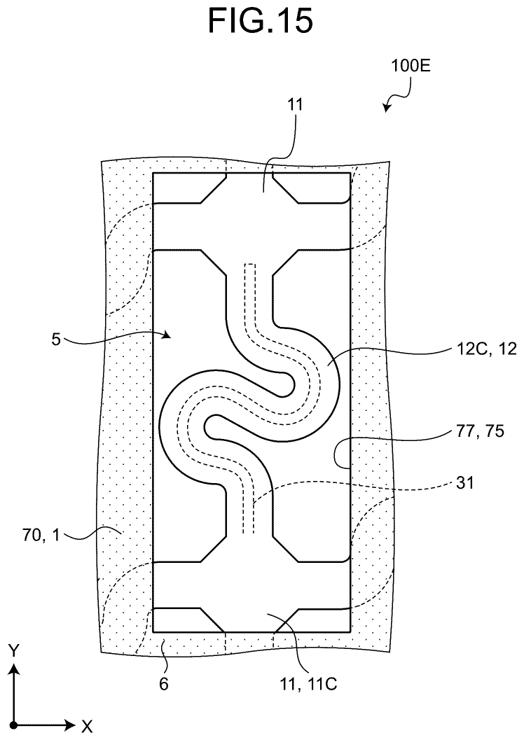

FIG. 15 is a plan view of the relation between the detection region and the stretchable substrate in the stretchable device according to a second modification. As illustrated in FIG. 15, the detection region 5 in a stretchable device 100E according to the second modification overlaps one hinge 12 (detection hinge 12C) and two bodies 11 (one of them is the detection body 11C) coupled to both ends of the detection hinge 12C. With the configuration according to the second modification, none of the detection hinges 12C are bonded to the first stretchable resin 60 or the second stretchable resin 70. Therefore, the detection hinge 12C does not follow the deformation of the first stretchable resin 60 and the second stretchable resin 70, and the strain gauge 31 does not detect noise (load in the first direction X).

### Third Modification

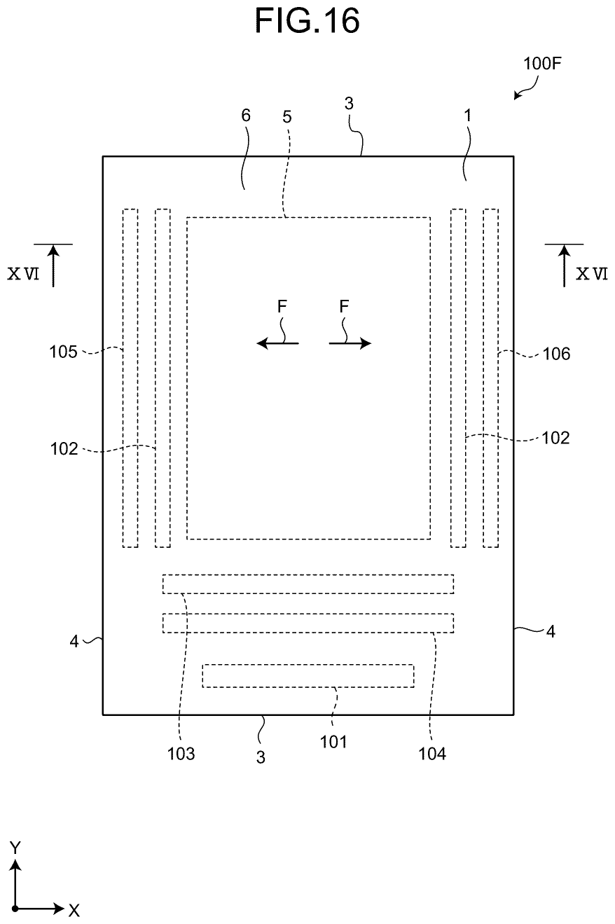

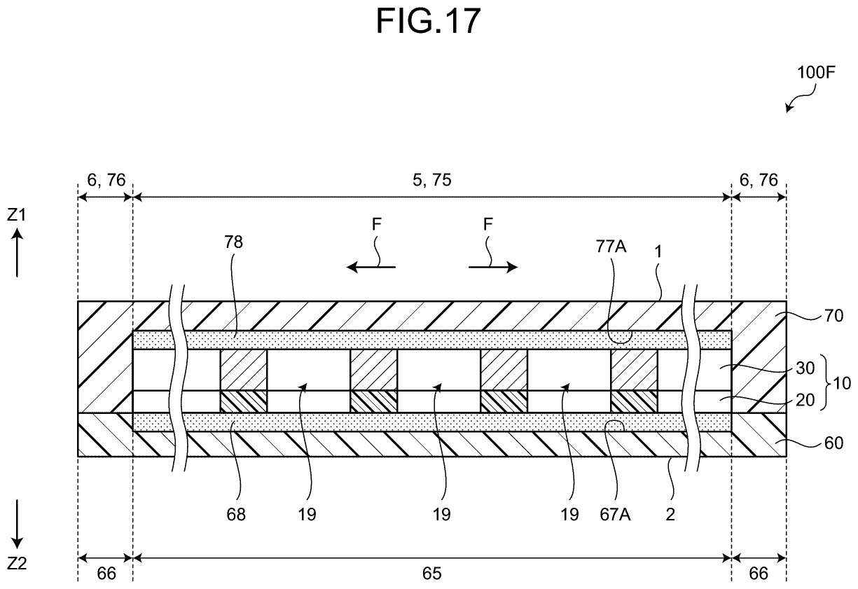

FIG. 16 is a plan view of the stretchable device according to a third modification. FIG. 17 is a sectional view of the stretchable device according to the third modification taken along the stacking direction. As illustrated in FIG. 17, in a stretchable device 100F according to the third modification, the first stretchable resin 60 and the second stretchable resin 70 have the recessed surfaces 67A and 77A, and the viscous fluids 68 and 78 are disposed in the recessed surfaces 67A and 77A as described in the second embodiment.

As illustrated in FIG. 16, the stretchable device 100F according to the third modification has a single detection region 5 larger than the detection region 5 according to the first embodiment. The detection region 5 according to the third modification is positioned at the center of the stretchable device 100F in the planar direction. The non-detection region 6 has a frame shape surrounding the detection region 5. In other words, the non-detection region 6 is positioned only at the ends (ends in the first direction X and the second direction X) of the stretchable substrate 10. Therefore, most of the hinges 12 of the stretchable substrate 10 are included in the detection region 5. This configuration can also reduce noise input to the strain gauge 31.

In the example according to the third modification, when the detection region 5 overlaps a plurality of hinges 12, the strain gauge 31 may be provided to all the hinges 12 overlapping the detection region 5 or may be provided to some of the hinges 12.

In the third modification, the non-detection region 6 has a frame shape. In other words, only the ends of the stretchable substrate 10 are bonded to the pair of stretchable resins (the first stretchable resin 60 and the second stretchable resin 70). When a tensile load acts not on the ends of the stretchable device 100F but only on part of the detection region 5 (refer to arrows F in FIGS. 16 and 17), the first stretchable resin 60 and the second stretchable resin 70 locally stretch. In other words, no load acts on the non-detection region 6 (bonded regions 66 and 76), so no load is transmitted to the stretchable substrate 10. Specifically, the stretchable device 100F according to the third modification fails to detect a load partially (locally) acting on the first stretchable resin 60 and the second stretchable resin 70. By contrast, in the configuration according to the first embodiment, a plurality of detection regions 5 are scattered, and the area of the bonded regions 66 and 76 is large. Therefore, the stretchable device 100 according to the first embodiment is more likely to detect a load partially (locally) acting on the first stretchable resin 60 and the second stretchable resin 70.

What is claimed is:

1. A stretchable device comprising:
a stretchable substrate comprising a plurality of bodies and a plurality of hinges that couple the bodies to each other; and
a pair of stretchable resins with the stretchable substrate interposed therebetween, wherein
the stretchable device includes a detection region in which a load is capable of being detected and a non-detection region when viewed in a stacking direction in which the stretchable substrate and the stretchable resins overlap,
one or more of the hinges are detection hinges each provided with a strain gauge,
all of the detection hinges overlap the detection region when viewed in the stacking direction, and
the stretchable resins each includes:
a bonded region that overlaps the non-detection region when viewed in the stacking direction and is bonded to the stretchable substrate; and
an unbonded region that overlaps the detection region when viewed in the stacking direction and is not bonded to the stretchable substrate.

2. The stretchable device according to claim 1, wherein, of the bodies, the body coupled to the detection hinge overlaps the detection region when viewed in the stacking direction.

3. The stretchable device according to claim 1, wherein the unbonded region has a hole passing through the stretchable resin.

4. The stretchable device according to claim 2, wherein the unbonded region has a hole passing through the stretchable resin.

5. The stretchable device according to claim 1, wherein
the stretchable resins each have:
a counter surface facing the stretchable substrate; and
an opposite surface facing opposite to the counter surface, and
the unbonded region is provided with a recessed surface recessed toward the opposite surface.

6. The stretchable device according to claim 2, wherein
the stretchable resins each have:
a counter surface facing the stretchable substrate; and
an opposite surface facing opposite to the counter surface, and
the unbonded region is provided with a recessed surface recessed toward the opposite surface.

7. The stretchable device according to claim 5, wherein a viscous fluid is disposed in the recessed surface.

8. The stretchable device according to claim 6, wherein a viscous fluid is disposed in the recessed surface.

9. The stretchable device according to claim 1, wherein the unbonded region is provided with a contact surface in contact with the stretchable substrate.

10. The stretchable device according to claim 2, wherein the unbonded region is provided with a contact surface in contact with the stretchable substrate.
